(19) United States
(12) Patent Application Publication
(10) Pub. No.: US 2023/0365412 A1
(43) Pub. Date: Nov. 16, 2023

(54) HEAT DISSIPATION SHEET FOR ELECTRONIC DEVICE AND MANUFACTURING METHOD THEREFOR

(71) Applicant: Samsung Electronics Co., Ltd., Suwon-si (KR)

(72) Inventors: Youngdo KIM, Suwon-si (KR); Chunmyung PARK, Suwon-si (KR)

(21) Appl. No.: 18/357,600

(22) Filed: Jul. 24, 2023

Related U.S. Application Data
(63) Continuation of application No. PCT/KR2022/002780, filed on Feb. 25, 2022.

(30) Foreign Application Priority Data
Mar. 31, 2021 (KR) 10-2021-0042237

(51) Int. Cl. C01B 32/23; H05K 7/20; H04M 1/02

(52) U.S. Cl. CPC C01B 32/23; H05K 7/20481; H04M 1/0268; H05K 7/20963

(57) ABSTRACT

A heat dissipation sheet is provided. The heat dissipation sheet has a plurality of graphene oxide particle layers including first graphene oxide particles having an average diameter of a first size and second graphene oxide particles having an average diameter of a second size, and a fine crease structure including pores with a thickness of less than 2 μm between the plurality of graphene oxide particle layers. Additionally, a manufacturing method for the heat dissipation sheet and a mobile communication device comprising the heat dissipation sheet are provided.

### CROSS-REFERENCE TO RELATED APPLICATION(S)

This application is a continuation application, claiming priority under § 365(c), of an International application No. PCT/KR2022/002780, filed on Feb. 25, 2022, which is based on and claims the benefit of a Korean patent application number 10-2021-0042237, filed on Mar. 31, 2021, in the Korean Intellectual Property Office, the disclosure of which is incorporated by reference herein in its entirety.

### BACKGROUND

### 1. Field

The disclosure relates to a heat dissipation sheet applicable to a foldable/rollable electronic device and a manufacturing technology thereof.

### 2. Description of Related Art

In an electronic device such as a smart phone or tablet, a heat can be generated from electronic parts such as a display or an application processor (AP). Since heat generation generally degrades the performance of various parts, it is very important to spread and solve the heat generated in the electronic device.

In order to eliminate the heat generated from the electronic device, materials such as a heat pipe, a heat sink, or a heat dissipation sheet are used. For example, an artificial graphite film has excellent price competitiveness, and has high mass productivity because it can be manufactured in a roll shape.

Meanwhile, recently, as a flexible display is applied, a foldable/rollable electronic device in which a usable display area is variable by folding the electronic device in half or rolling or sliding a part of the flexible display into the device is launched or is under development.

The above information is presented as background information only to assist with an understanding of the disclosure. No determination has been made, and no assertion is made, as to whether any of the above might be applicable as prior art with regard to the disclosure.

### SUMMARY

An artificial graphite film conventionally used as a heat dissipation sheet is not suitable for application to a foldable/rollable electronic device because numerous voids exist between a plurality of layers constituting the film. For example, in the case of the foldable electronic device, a heat generated in one area (e.g., an area where an AP is located) must be efficiently transferred to an opposite area around a hinge structure, so the heat dissipation sheet applied to the foldable electronic device requires, along with high heat conductivity, a sufficient tensile strength and elongation rate to withstand repetitive folding. However, since there are also many voids having sizes greater than 5 μm, which are identified through a cross-section of the artificial graphite film, it is not suitable to be applied to the foldable electronic device.

Aspects of the disclosure are to address at least the above-mentioned problems and/or disadvantages and to provide at least the advantages described below. Accordingly, an aspect of the disclosure is to provide a heat dissipation sheet that is applicable to a flexible display while maximizing heat transfer performance, a manufacturing method therefor, and an electronic device to which the heat dissipation sheet is applied.

Additional aspects will be set forth in part in the description which follows and, in part, will be apparent from the description, or may be learned by practice of the presented embodiments.

In accordance with an aspect of the disclosure, a heat dissipation sheet is provided. The heat dissipation sheet has a plurality of graphene oxide particle layers including first graphene oxide particles having an average diameter of a first size and second graphene oxide particles having an average diameter of a second size, and a fine crease structure including pores with a thickness of less than 2 μm between the plurality of graphene oxide particle layers.

In accordance with another aspect of the disclosure, a manufacturing method of a heat dissipation sheet is provided. The manufacturing method includes preparing a dispersion liquid by using a graphene oxide aqueous dispersion solution by compounding first graphene oxide particles having an average diameter of a first size and second graphene oxide particles having an average diameter of a second size in a specified weight ratio, providing an initial film by applying or coating the dispersion liquid on a substrate, performing annealing on the initial film, and providing a heat dissipation sheet by compressing the initial film on which the annealing has been performed.

In accordance with another aspect of the disclosure, a mobile communication device is provided. The mobile communication device includes a housing including a first housing and a second housing rotatable with respect to the first housing, a flexible display disposed over the first housing and the second housing, a first reinforcing plate disposed to correspond to the first housing beneath the flexible display and a second reinforcing plate disposed to correspond to the second housing, and a heat dissipation sheet attached to the first reinforcing plate, the second reinforcing plate, and the flexible display, between the first reinforcing plate and second reinforcing plate and the flexible display. The heat dissipation sheet includes a plurality of graphene oxide particle layers including first graphene oxide particles having an average diameter of a first size and second graphene oxide particles having an average diameter of a second size, and has a fine crease structure including pores with a thickness of less than 2 μm between the graphene oxide particle layers.

According to various embodiments of the disclosure, a heat dissipation sheet having better heat dissipation performance and durability than a conventional heat dissipation sheet using graphite may be provided.

Also, according to various embodiments, by applying a heat dissipation sheet having excellent elongation rate and heat dissipation performance to a flexible display, effective heat dissipation performance may be achieved in a foldable/rollable electronic device in which display deformation repeatedly occurs.

Also, according to various embodiments, a production process of a heat dissipation sheet includes a process of oxidation and carbonization of polymer particles for improving mechanical properties, whereby the production process of the heat dissipation sheet may be efficient.

In addition to this, various effects identified directly or indirectly through the disclosure may be provided.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 illustrates the compounding of graphene oxide particles according to an embodiment of the disclosure;

FIG. 2 is a flowchart illustrating a manufacturing process of a heat dissipation sheet according to an embodiment of the disclosure;

FIG. 3 illustrates a process of oxidation and carbonization of polyacrylonitrile (PAN) particles according to an embodiment of the disclosure;

FIG. 4 is a diagram showing the oxidation and carbonization process of FIG. 3 by a chemical formula according to an embodiment of the disclosure;

FIG. 5 illustrates cross-section images of a heat dissipation sheet using graphene oxide particles and a conventional graphite sheet, which are photographed using a scanning electron microscope (SEM) according to an embodiment of the disclosure;

FIG. 6 is a graph comparing elongation rates of a heat dissipation sheet and a conventional graphite sheet according to an embodiment of the disclosure;

FIG. 7 illustrates an environment for evaluating the heat dissipation performance of a heat dissipation sheet for a heat source according to an embodiment of the disclosure;

FIG. 8 illustrates a cross-sectional view of a foldable electronic device to which a heat dissipation sheet according to an embodiment of the disclosure; and

FIG. 9 is a diagram illustrating an electronic device within a network environment 900 according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments escribed herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

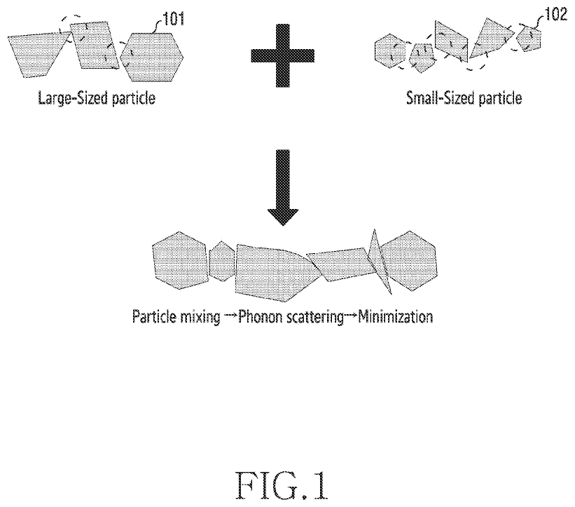

FIG. 1 illustrates the compounding of graphene oxide particles according to an embodiment of the disclosure.

Referring to FIG. 1, a concept of compounding graphene oxide particles having different sizes is shown. In order to maximize a thermal conductivity of a heat dissipation sheet, it is efficient to compound graphene oxide particles having a large particle size and graphene oxide particles having a relatively small particle size in an appropriate ratio, rather than simply using graphene particles having a large particle size through a graphite exfoliation process.

For example, as shown in FIG. 1, when first graphene oxide particles 101 averagely having a first size and second graphene oxide particles 102 having a second size smaller than the first size are properly compounded, phonon scattering may be minimized. The phonon scattering is very important in terms of thermal conduction. When thermal conduction occurs in the heat dissipation sheet, as a phonon scattering phenomenon occurs much, thermal conductivity may decrease. Also, as a temperature increases, the phonon scattering phenomenon increases. Therefore, as the phonon scattering phenomenon of the heat dissipation sheet increases, the heat dissipation sheet becomes inefficient in thermal conductivity, particularly at a high temperature, which deteriorates heat dissipation performance in a mobile communication device in which a plurality of heat sources are disposed in a small mounting space. Therefore, it is more advantageous in terms of heat dissipation performance to provide a heat dissipation sheet by using graphene oxide particles of different sizes than to provide a heat dissipation sheet by using graphene oxide particles of a single size.

In an embodiment, an average size of the first graphene oxide particles 101 may be about 20 μm. Here, the average size may mean an average diameter of particles. For example, the first graphene oxide particles 101 may have a size between 18 μm and 22 μm. In an embodiment, an average size of the second graphene oxide particles 102 may be about 4 μm. For example, the second graphene oxide particles 102 may have a size between 3 μm and 5 μm.

In various embodiments, the sizes of the first graphene oxide particles 101 and the second graphene oxide particles 102 may be selected in an appropriate ratio. For example, the sizes of the first graphene oxide particles 101 and the second graphene oxide particles 102 may have a ratio of about 5:1. However, in another example, the size of the first graphene oxide particles 101 and the second graphene oxide particles 102 may have a ratio of about 4:1 or 6:1.

In an embodiment, the first graphene oxide particles 101 may be acquired through a graphite exfoliation process. However, various known techniques for acquiring graphene oxide particles may be applied to acquiring the first graphene oxide particles 101. Also, the second graphene oxide particles 102 may be acquired by additionally applying an ultrasonic treatment process to the first graphene oxide particles 101.

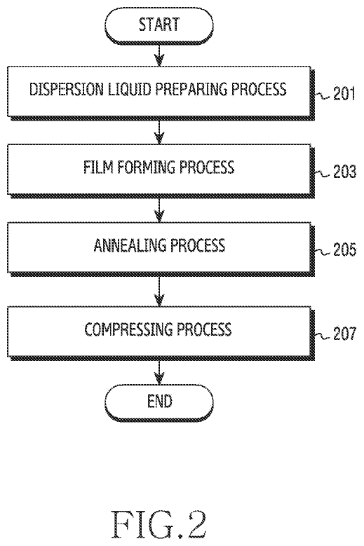

FIG. 2 is a flowchart illustrating a manufacturing process of a heat dissipation sheet according to an embodiment of the disclosure.

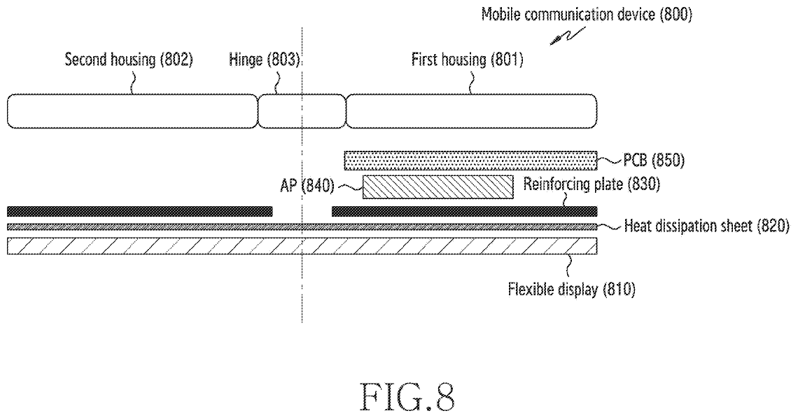

Referring to FIG. 2, the manufacturing process of the heat dissipation sheet may include a dispersion liquid preparation process 201 of preparing a dispersion liquid by using graphene oxide particles having different sizes. In an embodiment, a graphene oxide aqueous dispersion solution may be prepared by dispersing, in distilled water, the first graphene oxide particles 101 and the second graphene oxide particles 102 compounded in an appropriate mass ratio. For example, the first graphene oxide particles 101 and the second graphene oxide particles 102 may have a mass ratio of 70:30. In another example, the first graphene oxide particles 101 and the second graphene oxide particles 102 may have a mass ratio of 50:50 or 30:70. The structure and performance of the heat dissipation sheet provided through each mass ratio will be described later with reference to FIG. 8.

In an embodiment, in addition to the first graphene oxide particles 101 and the second graphene oxide particles 102, a polyacrylonitrile (PAN) polymer may be further compounded with the dispersion liquid so as to increase thermal conductivity and mechanical properties (e.g., tensile performance) of the heat dissipation sheet. For example, a PAN aqueous dispersion solution may be added to the above-described graphene oxide aqueous dispersion solution. Here, the PAN aqueous dispersion solution may be prepared by dispersing PAN particles having an appropriately selected high molecular weight in distilled water. In an example, a molecular weight of PAN particles may be about 30,000 g/mol. For example, the molecular weight of the PAN particles may be determined between values of 3,000 g/mol and 50,000 g/mol. Also, a mass ratio of the PAN particles to the graphene oxide particles may be determined to be 1 wt %.

In an embodiment, the graphene oxide particles and/or the PAN particles may be dispersed in a suitable organic solvent other than the distilled water.

In an embodiment, the manufacturing process of the heat dissipation sheet may include a film forming process 203 of applying or coating the dispersion liquid prepared in the dispersion liquid preparation process 201 to a substrate. In an embodiment, the substrate may be polyethylene terephthalate (PET) or a stainless steel plate. However, the type of the substrate is not limited thereto, and an appropriate substrate for providing an initial film may be selected.

In an embodiment, an initial film corresponding to an initial stage of the heat dissipation sheet may be prepared through a process of bar coating the dispersion liquid on the substrate. In another embodiment, the initial film may be prepared by applying the dispersion liquid to the substrate and separating the film from the substrate after the dispersion liquid is dried. In addition to this, an appropriate technique for providing a film by using a dispersion liquid prepared through the dispersion liquid preparation process 201 may be applied.

In an embodiment, an annealing process 205 may be performed on the initial film formed through the film forming process 203. The annealing process 205 may include the steps of heating, maintaining a high temperature, and cooling. For example, the initial film formed through the film forming process 203 may be heated to a high temperature of 2300° C. or higher, and be maintained at the high temperature for a predetermined time. Thereafter, a process of slowly cooling to a room temperature may be performed.

In an embodiment, air pockets may be formed between graphene layers constituting the film through the annealing process 205. Also, artifacts that may occur in the heat dissipation sheet may be removed while the removal of residual stress, the improvement of ductility, etc. occur through the annealing process 205.

In an embodiment, the annealing process 205 may include the processes of slowly heating the film to a first temperature (e.g., 2300° C.) that is a specified high temperature, maintaining the film at the first temperature for a period of time, and then again slowly cooling to a second temperature (e.g., 50° C.) (e.g., cooling at about 20° C. per hour), and cooling through natural convection at a room temperature from the second temperature. However, in another embodiment, the annealing process 205 may be also performed through a process of cooling through natural convection directly at the first temperature.

In an embodiment, a compression process 207 may be performed on the film on which the annealing process has been performed. A specific fine crease structure (e.g., a micro fold structure) may be formed through compression.

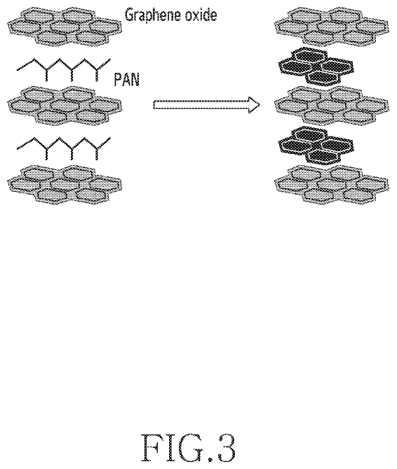

FIG. 3 illustrates a process of oxidation and carbonization of PAN particles according to an embodiment of the disclosure.

When the dispersion liquid described above with reference to FIG. 2 includes PAN particles, the oxidation and carbonization process may be required in order for the PAN particles to enhance mechanical properties (e.g., tensile strength, elongation force) by interacting with graphene particles. However, according to an embodiment of the disclosure, a graphene film in which a polymer such as PAN is inserted may be implemented through a process of graphitization at a high temperature.

For example, referring to FIG. 3, while the film is maintained at a high temperature in the above-described annealing process 205, the PAN particles may be disposed in a layer shape between graphene oxide layers. That is, intercalation may be performed while polymer functional groups of the PAN particles form hydrogen bonds with functional groups of the graphene oxide particles. Afterwards, through the carbonization process, the inserted polymer acts as an additional carbon source, and defects that may occur may be supplemented.

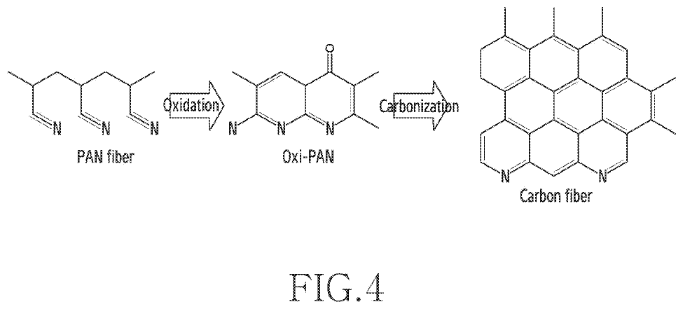

FIG. 4 is a diagram showing the oxidation and carbonization process of FIG. 3 by a chemical formula according to an embodiment of the disclosure.

Referring to FIG. 4, a PAN particle may include a triple bond between C and N. While a high temperature is maintained through the annealing process 205, the triple bond between C and N of the PAN particle may be converted into a double bond between C and N, and the PAN particle may be deformed to have a benzene ring form. Then, as the double bond between C and N is changed into a single bond through a carbonization process, the PAN particle may have a layered structure. C contained in the PAN particle having the layered structure may strengthen a bond and improve thermal conductivity and tensile ability while acting as an additional carbon source for graphene oxide particles.

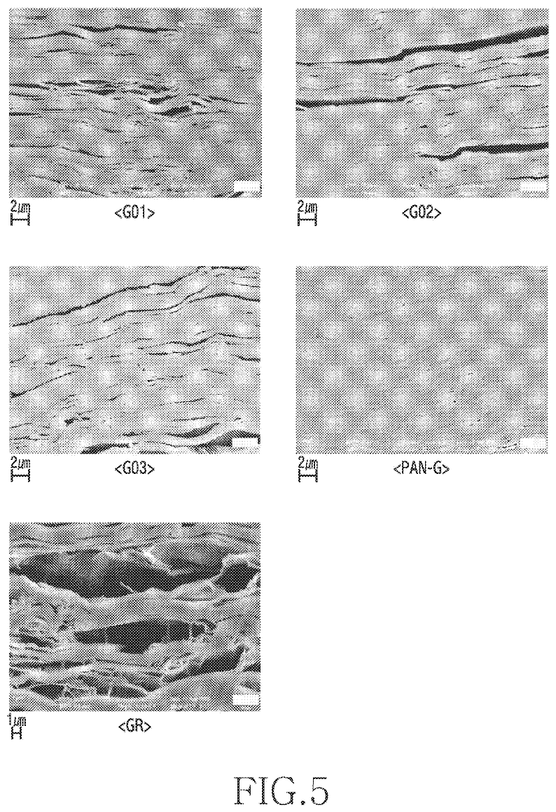

FIG. 5 shows cross-section images of a heat dissipation sheet using graphene oxide particles and a conventional graphite sheet, which are photographed using a scanning electron microscope (SEM) according to an embodiment of the disclosure.

Referring to FIG. 5, <GR> shows a cross section of the conventional graphite sheet. <G01>, <G02>, and <G03> show cross sections of a heat dissipation sheet provided using a graphene oxide particle aqueous dispersion solution obtained by compounding the first graphene oxide particles 101 and the second graphene oxide particles 102 in a predetermined ratio. <PAN-G> shows a cross section of a heat dissipation sheet provided using a dispersion liquid obtained by mixing a PAN particle aqueous dispersion solution with a graphene oxide particle aqueous dispersion solution obtained by compounding the first graphene oxide particles 101 and the second graphene oxide particles 102 in a weight ratio of 50:50. In a sample of <PAN-G>, a weight ratio of the graphene oxide particles and PAN particles was 1%. A particle size compounding ratio and a measured thermal conductivity of each sample are shown in Table 1 below. In Table 1, a particle size compounding ratio means a compounding ratio of the first graphene oxide particles 101 and the second graphene oxide particles 102.

TABLE 1

| | Particle size | | Thermal |
|---|---|---|---|
| | compounding ratio | Density | conductivity |
| Sample | (wt %) | (g/cm³) | (W/mK) |
| G01 | 70:30 | 1.98 | 998 |
| G02 | 50:50 | 1.99 | 1030 |
| G03 | 30:70 | 1.96 | 942 |
| PAN-G | 50:50 | 2.02 | 1209 |
| GR | — | 1.61 | 790 |

For reference, the G02 sample in which the particle size compounding ratio of the first graphene oxide particles 101 and the second graphene oxide particles 102 is 50:50 has the highest thermal conductivity among heat dissipation sheets that use only graphene oxide particles, and accordingly, the compounding ratio of the first graphene oxide particles 101 and the second graphene oxide particles 102 in the PAN-G sample was 50:50, which is the same as that of the G02 sample. Also, it may be confirmed that the PAN-G sample has the highest thermal conductivity among all samples. It may be confirmed that the heat dissipation sheets of various embodiments have a thermal conductivity of 900 W/mK or more.

Referring again to FIG. 5, it may be seen that all of the heat dissipation films G01, G02, and G03 prepared using different graphene oxide particles have a significantly improved fine crease structure compared to the conventional GR. In particular, it may be confirmed that a length of a GR void in a thickness direction is 3 μm to 5 μm or more, whereas a thickness of a void identified in G01, G02, and G03 is less than 2 μm. Also, it may be confirmed that a density of the heat dissipation sheet of various embodiments is higher than that of the conventional GR by the improvement of the fine crease structure. For example, the GR has a density of 1.61 g/cm³, whereas the PAN-G has a density of 2.02 g/cm³.

Referring continuously to FIG. 5, it may be confirmed that the heat dissipation sheet PAN-G provided using an aqueous dispersion solution obtained by additionally adding PAN particles to the first graphene oxide particles 101 and the second graphene oxide particles 102 has a fine crease structure more improved than not only the GR but also the G01, G02, and G03. In the PAN-G, it may be confirmed that voids are hardly confirmed through fine creases or it has voids of less than 0.5 μm.

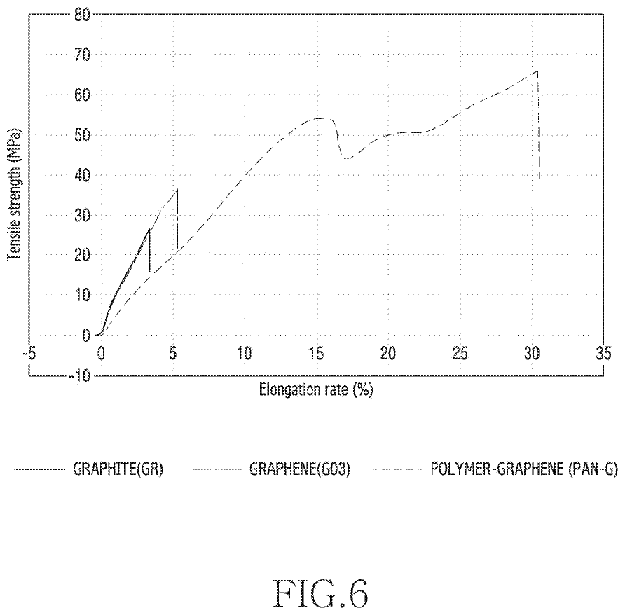

Through the structure of the heat dissipation sheet that may be confirmed through FIG. 5, it may be seen that a heat dissipation film of various embodiments is superior to the conventional graphite sheet in terms of an elongation rate dependent on a tensile strength. In this regard, the elongation rate dependent on the tensile strength will be described with reference to FIG. 6.

FIG. 6 is a graph comparing elongation rates of a heat dissipation sheet and a conventional graphite sheet according to an embodiment of the disclosure. For reference, for the sake of comparison convenience, the graph shows only the experimental result of the G03 sample, in a heat dissipation film in which graphene oxide particles having different sizes are compounded and PAN polymer particles are not added.

In the conventional graphite sheet, it may be confirmed that the elongation rate is less than 4% at a tensile strength of about 26 MPa. The conventional graphite sheet is broken without withstanding a tensile strength of 26 MPa or more.

In the G03 sample in which the first graphene oxide particles 101 and the second graphene oxide particles 102 are compounded at a ratio of 3:7, it was confirmed that the elongation rate was up to about 5% or more while a tensile strength was withstood up to 37 MPa.

In the PAN-G sample in which the graphene oxide particles and the PAN particles are compounded together, it was confirmed to show excellent physical properties that could not be observed in not only an artificial graphite sheet but also a single graphene material. In particular, in the PAN-G sample, as shown in the graph of FIG. 6, all elastic and plastic deformation regions observable in ductile materials may be confirmed, and a very good elongation rate of maximal about 30% is shown. It may be confirmed that the PAN-G sample also endures even a tensile strength of 60 MPa or more.

A tensile strength at a maximum elongation rate of each sample is shown in Table 2.

TABLE 2

| | | Maximum elongation |
|---|---|---|
| Sample | Tensile strength (MPa) | rate (%) |
| GR | 26.4 | 3.60 |
| G03 | 38.6 | 5.4 |
| PAN-G | 68.4 | 22.4 |

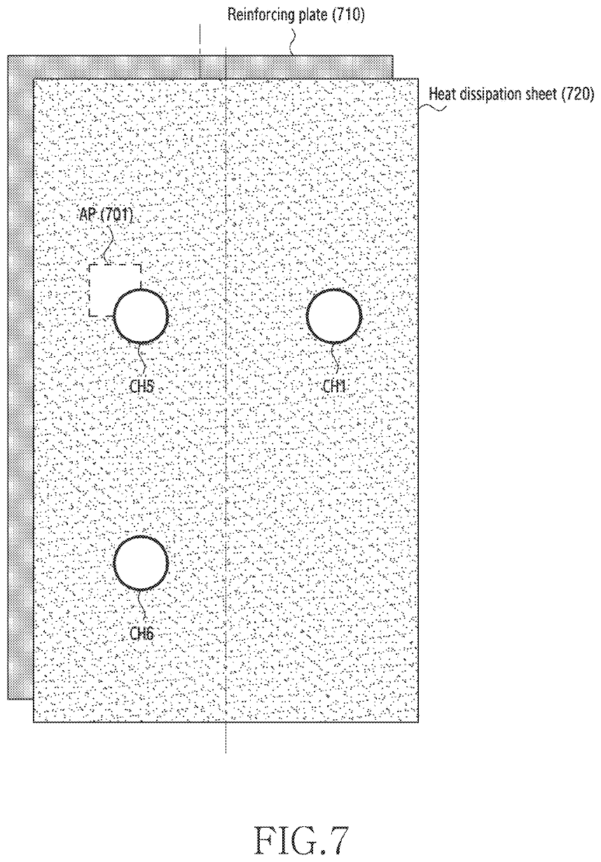

In an electronic device mounting a processor such as an AP, in order to check heat dissipation performance for heat generation, it is necessary to check actual heat transfer performance in addition to the thermal conductivity values mentioned in Table 1. This will be described with reference to FIG. 7.

FIG. 7 illustrates an environment for evaluating the heat dissipation performance of a heat dissipation sheet for a heat source according to an embodiment of the disclosure. The heat dissipation performance of the heat dissipation sheet may be measured by, after attaching a heat dissipation sheet 720 to a reinforcing plate 710, comparing a temperature of a point corresponding to a heat source 701 and a temperature of a point spaced a predetermined distance or more apart from the heat source 701 in a horizontal direction. The heat source 701, which is an AP of a smart phone, was disposed on a front surface of the reinforcing plate 710 to which the heat dissipation sheet is attached, and a measurement point was located on a rear surface of the heat dissipation sheet 720. FIG. 7 may be understood as a diagram looking at the heat dissipation sheet 720 on the rear surface. It may be understood that the AP, that is, the heat source 701 is not visible because it is hidden by the heat dissipation sheet 720 and the reinforcing plate 710, and is attached to a position corresponding to CH5 on the opposite surface of the reinforcing plate 710.

Thermal conductivity was measured using a thermocouple. Assuming a foldable electronic device, Table 3 shows the temperature and heat dissipation performance of each channel before repetitive folding is applied to each sample, when a point where the AP is located is CH5, a point located on the same side as the AP with a criterion of a folding axis is CH6, a point located on a side opposite the AP with a criterion of the folding axis is CH1, a temperature of the heat source is 70° C. and a thickness of the reinforcing plate is 400 μm. For reference, the heat dissipation performance was determined based on a temperature difference between CH5 and CH1, and it is meant that the lower the value is, the higher the heat dissipation performance is.

TABLE 3

| | | | | Heat |
|---|---|---|---|---|
| | | | | Dissipation |
| | | | | Performance |
| | | | | (ΔT = CH5 − |
| Sample | CH5 | CH1 | CH6 | CH1) |
| G01 | 51.2 (±0.07) | 36.6 (±0.08) | 38.9 (±0.08) | 14.5 |
| G02 | 50.8 (±0.07) | 36.0 (±0.12) | 38.2 (±0.12) | 14.8 |
| G03 | 50.8 (±0.14) | 36.1 (±0.14) | 38.3 (±0.14) | 14.8 |
| PAN-G | 50.2 (±0.08) | 36.5 (±0.08) | 39.2 (±0.06) | 13.7 |
| GR | 52.4 (±0.09) | 35.3 (±0.10) | 38.3 (±0.11) | 17.0 |

Referring to Table 4, it may be confirmed that, compared to the conventional graphite sheet showed a temperature difference of about 17° C., the G01, G02, and G03 heat dissipation sheets prepared by compounding graphene oxide particles showed a temperature difference of about 14.8° C. and thus, have a relatively excellent thermal conductivity. Also, it may be confirmed that the PAN-G heat dissipation sheet prepared through the compounding of graphene oxide particles and PAN particles showed a temperature difference of about 13.7° C. and thus, has a better thermal conductivity than not only the graphite sheet but also the G01, G02, and G03 heat dissipation sheets.

In order to use the development sheet of various embodiments as a heat dissipation sheet of a foldable electronic device, excellent heat transfer performance must be maintained even after a plurality of repetitive folding. Accordingly, in a state in which two reinforcing plates spaced a hinge interval (about 7.5 mm) apart are attached to and laminated with a heat dissipation sheet, one reinforcing plate was fastened to a jig, and folding was performed 400,000 times to give a value of 1.5R, and then the heat dissipation performance was checked. The folding speed was 1.3 sec/cycle, the delay between folding was 0.7 sec/cycle, and a temperature of the heat source, a position of a channel for temperature measurement, and the like were measured under the same conditions as in Table 3. The measurement results are shown in Table 4. Only measurement data of the G03 among the heat dissipation sheets that use the graphene oxide particles was representatively shown.

TABLE 4

| | | | | Heat |
|---|---|---|---|---|
| | | | | Dissipation |
| | | | | Performance |
| | | | | (ΔT = CH5 − |
| Sample | CH5 | CH1 | CH6 | CH1) |
| G03 | 50.8 (±0.22) | 35.5 (±0.19) | 37.8 (±0.24) | 15.3 |
| PAN-G | 50.4 (±0.07) | 36.0 (±0.08) | 38.2 (±0.07) | 14.4 |
| GR | 52.4 (±0.11) | 34.6 (±0.13) | 38.4 (±0.16) | 17.8 |

As may be confirmed in Table 4, the overall heat dissipation performance is somewhat lower than before the folding test, but the G03 sample and the PAN-G sample still showed excellent heat dissipation performance because showing a temperature difference of 15.3° C. and 14.4° C., respectively. That is, a manufacturing process of the heat dissipation sheet using the compounding of the graphene oxide particles and the insertion of the PAN polymer proposed in various embodiments greatly improves the overall heat dissipation performance and mechanical properties of the heat dissipation sheet. Also, the heat dissipation sheet of various embodiments may present excellent heat dissipation performance and durability under actual use conditions even when applied to a new form factor such as a foldable or rollable electronic device in which multiple folding occurs. For reference, it is expected that the number of folding will not exceed about 200,000 times during a total period of general user's use of the foldable electronic device.

FIG. 8 illustrates a cross-sectional view of a foldable electronic device to which a heat dissipation sheet according to an embodiment of the disclosure.

Referring to FIG. 8, the foldable electronic device may be understood as a mobile communication device 800 such as a smart phone. The mobile communication device 800 may include a housing which includes a first housing 801 and a second housing 802 rotatable with respect to the first housing 801. The housing may further include a hinge 803 connecting the first housing 801 and the second housing 802, and the first housing 801 may rotate relative to the second housing 802 by using a rotational structure given to the hinge 803.

In an embodiment, the housing of the mobile communication device 800 may form at least a part of a rear surface and a side surface of the mobile communication device 800, in a state where the mobile communication device 800 is unfolded. The flexible display 810 may be disposed to form the front surface of the mobile communication device 800 over the first housing 801 and the second housing 802.

In an embodiment, the flexible display 810 may be understood as a concept including a cover window, a color layer, a polarizing plate, and an adhesive layer. The flexible display 810 is sufficient to be deformable as the housing is folded or unfolded around a folding axis, and is not particularly limited in its type or stacked structure.

In an embodiment, a heat dissipation sheet 820 of various embodiments may be disposed beneath the flexible display 810. The heat dissipation sheet 820 may correspond to any one of the aforementioned G01, G02, G03, and PAN-G. However, the heat dissipation sheet 820 is not limited to these examples, and may refer to graphene oxide particles having different sizes, or a heat dissipation sheet prepared by compounding graphene oxide particles having different sizes and a PAN polymer. For example, the heat dissipation sheet 820 may include a plurality of graphene oxide particle layers including first graphene oxide particles having an average diameter of a first size and second graphene oxide particles having an average diameter of a second size, and have a fine crease structure including pores with a thickness of less than 2 μm between the graphene oxide particle layers.

In an embodiment, a reinforcing plate 830 may be disposed at a bottom of the heat dissipation sheet 820. The reinforcing plate 830 may include a first reinforcing plate corresponding to the first housing 801 and a second reinforcing plate corresponding to the second housing 802. In an embodiment, the heat dissipation sheet 820 may be attached to the reinforcing plate 830 and the flexible display 810, between the reinforcing plate 830 and the flexible display 810. In an embodiment, an adhesive agent or adhesive tape, etc. may be used to attach the heat dissipation sheet 820.

In the embodiment of FIG. 8, each component is shown with a predetermined distance, but this is for description convenience, and may be closely attached/adhered with appropriate tolerances or without substantial gaps according to a general assembly method of an electronic device.

In an embodiment, the mobile communication device 800 may further include a printed circuit board (PCB) 850 and an AP 840 disposed on the PCB 850. The AP 840 may be understood as a kind of heat source. In various embodiments, in addition to the AP 840, various components such as a memory, a modem, a camera module, an antenna, or a battery may act as the heat source. The heat dissipation sheet 820 may effectively diffuse a heat provided from a predetermined heat source, to an opposite display area.

A heat dissipation sheet of an embodiment may have a plurality of graphene oxide particle layers including first graphene oxide particles having an average diameter of a first size and second graphene oxide particles having an average diameter of a second size; and a fine crease structure including pores with a thickness of less than 2 μm between the plurality of graphene oxide particle layers.

In an embodiment, the first size may be 18 μm to 22 μm, and the second size may be 3 μm to 5 μm.

In an embodiment, a weight ratio of the first graphene oxide particles and the second graphene oxide particles may be 50:50.

In an embodiment, the heat dissipation sheet may have a thermal conductivity of 900 W/mK or more.

In an embodiment, the heat dissipation sheet may be formed by the first graphene oxide particles, the second graphene oxide particles, and polyacrylonitrile (PAN) particles.

In an embodiment, the heat dissipation sheet may further include a layered structure formed by the PAN particles between the plurality of graphene oxide particle layers. A weight ratio of the PAN particles to the first graphene oxide particles and second graphene oxide particles is 1%. Also, a molecular weight of the PAN particles may have a value between 3,000 g/mol to 50,000 g/mol. The heat dissipation sheet may have a thermal conductivity of 1200 W/mK or more. The heat dissipation sheet may have a void of less than 0.5 μm.

A manufacturing method of a heat dissipation sheet of an embodiment may include the processes of: preparing a dispersion liquid by using a graphene oxide aqueous dispersion solution by compounding first graphene oxide particles having an average diameter of a first size and second graphene oxide particles having an average diameter of a second size in a specified weight ratio; providing an initial film by applying or coating the dispersion liquid on a substrate; performing annealing on the initial film; and providing a heat dissipation sheet by compressing the initial film on which the annealing has been performed.

In an embodiment, the process of preparing the dispersion liquid may include the processes of: preparing a PAN aqueous dispersion solution by dispersing PAN particles in distilled water; and mixing the PAN aqueous dispersion solution and the graphene oxide aqueous dispersion solution.

In an embodiment, the process of providing the initial film may include the processes of: applying or coating the dispersion liquid on a substrate; and separating the initial film provided by the dispersion liquid from the substrate.

In an embodiment, the process of performing the annealing includes the processes of: maintaining the initial film in a high temperature state above a specified temperature; and cooling the initial film. Here, the specified temperature may be 2300° C.

A mobile communication device of an embodiment may include a housing including a first housing and a second housing rotatable with respect to the first housing; a flexible display disposed over the first housing and the second housing; a first reinforcing plate disposed to correspond to the first housing beneath the flexible display and a second reinforcing plate disposed to correspond to the second housing; and a heat dissipation sheet attached to the first reinforcing plate and second reinforcing plate and the flexible display, between the first reinforcing plate and second reinforcing plate and the flexible display. The heat dissipation sheet may include a plurality of graphene oxide particle layers formed by first graphene oxide particles having an average diameter of a first size and second graphene oxide particles having an average diameter of a second size, and have a fine crease structure including pores with a thickness of less than 2 μm between the graphene particle layers.

In an embodiment, a heat source may be disposed beneath the first reinforcing plate. The heat source may include at least one of an application processor (AP), a memory, a modem, a camera, an antenna, and a battery.

In an embodiment, the mobile communication device may further include a printed circuit board (PCB), and the heat source may be disposed on the PCB.

In an embodiment, the heat dissipation sheet may be formed by the first graphene oxide particles, the second graphene oxide particles, and polyacrylonitrile (PAN) particles.

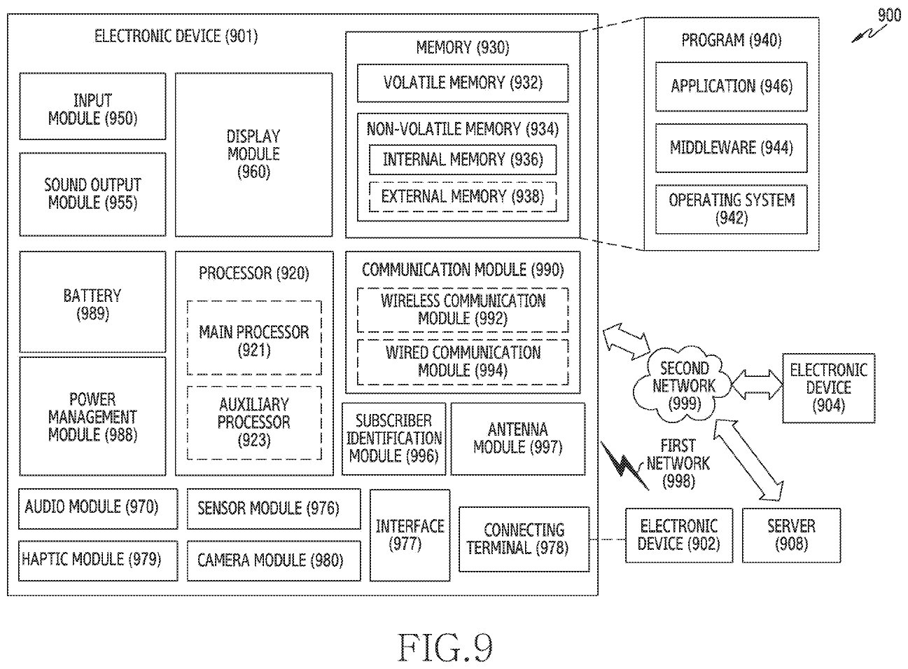

FIG. 9 is a block diagram illustrating an electronic device 901 in a network environment 900 according to an embodiment of the disclosure.

Referring to FIG. 9, the electronic device 901 in the network environment 900 may communicate with an electronic device 902 via a first network 998 (e.g., a short-range wireless communication network), or at least one of an electronic device 904 or a server 908 via a second network 999 (e.g., a long-range wireless communication network). According to an embodiment, the electronic device 901 may communicate with the electronic device 904 via the server 908. According to an embodiment, the electronic device 901 may include a processor 920, memory 930, an input module 950, a sound output module 955, a display module 960, an audio module 970, a sensor module 976, an interface 977, a connecting terminal 978, a haptic module 979, a camera module 980, a power management module 988, a battery 989, a communication module 990, a subscriber identification module (SIM) 996, or an antenna module 997. In some embodiments, at least one of the components (e.g., the connecting terminal 978) may be omitted from the electronic device 901, or one or more other components may be added in the electronic device 901. In some embodiments, some of the components (e.g., the sensor module 976, the camera module 980, or the antenna module 997) may be implemented as a single component (e.g., the display module 960).

The processor 920 may execute, for example, software (e.g., a program 940) to control at least one other component (e.g., a hardware or software component) of the electronic device 901 coupled with the processor 920, and may perform various data processing or computation. According to one embodiment, as at least part of the data processing or computation, the processor 920 may store a command or data received from another component (e.g., the sensor module 976 or the communication module 990) in volatile memory 932, process the command or the data stored in the volatile memory 932, and store resulting data in non-volatile memory 934. According to an embodiment, the processor 920 may include a main processor 921 (e.g., a central processing unit (CPU) or an application processor (AP)), or an auxiliary processor 923 (e.g., a graphics processing unit (GPU), a neural processing unit (NPU), an image signal processor (ISP), a sensor hub processor, or a communication processor (CP)) that is operable independently from, or in conjunction with, the main processor 921. For example, when the electronic device 901 includes the main processor 921 and the auxiliary processor 923, the auxiliary processor 923 may be adapted to consume less power than the main processor 921, or to be specific to a specified function. The auxiliary processor 923 may be implemented as separate from, or as part of the main processor 921.

The auxiliary processor 923 may control at least some of functions or states related to at least one component (e.g., the display module 960, the sensor module 976, or the communication module 990) among the components of the electronic device 901, instead of the main processor 921 while the main processor 921 is in an inactive (e.g., sleep) state, or together with the main processor 921 while the main processor 921 is in an active state (e.g., executing an application). According to an embodiment, the auxiliary processor 923 (e.g., an image signal processor or a communication processor) may be implemented as part of another component (e.g., the camera module 980 or the communication module 990) functionally related to the auxiliary processor 923. According to an embodiment, the auxiliary processor 923 (e.g., the neural processing unit) may include a hardware structure specified for artificial intelligence model processing. An artificial intelligence model may be generated by machine learning. Such learning may be performed, e.g., by the electronic device 901 where the artificial intelligence is performed or via a separate server (e.g., the server 908). Learning algorithms may include, but are not limited to, e.g., supervised learning, unsupervised learning, semi-supervised learning, or reinforcement learning. The artificial intelligence model may include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 930 may store various data used by at least one component (e.g., the processor 920 or the sensor module 976) of the electronic device 901. The various data may include, for example, software (e.g., the program 940) and input data or output data for a command related thereto. The memory 930 may include the volatile memory 932 or the non-volatile memory 934.

The program 940 may be stored in the memory 930 as software, and may include, for example, an operating system (OS) 942, middleware 944, or an application 946.

The input module 950 may receive a command or data to be used by another component (e.g., the processor 920) of the electronic device 901, from the outside (e.g., a user) of the electronic device 901. The input module 950 may include, for example, a microphone, a mouse, a keyboard, a key (e.g., a button), or a digital pen (e.g., a stylus pen).

The sound output module 955 may output sound signals to the outside of the electronic device 901. The sound output module 955 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 960 may visually provide information to the outside (e.g., a user) of the electronic device 901. The display module 960 may include, for example, a display, a hologram device, or a projector and control circuitry to control a corresponding one of the display, hologram device, and projector. According to an embodiment, the display module 960 may include a touch sensor adapted to detect a touch, or a pressure sensor adapted to measure the intensity of force incurred by the touch.

The audio module 970 may convert a sound into an electrical signal and vice versa. According to an embodiment, the audio module 970 may obtain the sound via the input module 950, or output the sound via the sound output module 955 or a headphone of an external electronic device (e.g., an electronic device 902) directly (e.g., wiredly) or wirelessly coupled with the electronic device 901.

The sensor module 976 may detect an operational state (e.g., power or temperature) of the electronic device 901 or an environmental state (e.g., a state of a user) external to the electronic device 901, and then generate an electrical signal or data value corresponding to the detected state. According to an embodiment, the sensor module 976 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 977 may support one or more specified protocols to be used for the electronic device 901 to be coupled with the external electronic device (e.g., the electronic device 902) directly (e.g., wiredly) or wirelessly. According to an embodiment, the interface 977 may include, for example, a high definition multimedia interface (HDMI), a universal serial bus (USB) interface, a secure digital (SD) card interface, or an audio interface.

A connecting terminal 978 may include a connector via which the electronic device 901 may be physically connected with the external electronic device (e.g., the electronic device 902). According to an embodiment, the connecting terminal 978 may include, for example, an HDMI connector, a USB connector, an SD card connector, or an audio connector (e.g., a headphone connector).

The haptic module 979 may convert an electrical signal into a mechanical stimulus (e.g., a vibration or a movement) or electrical stimulus which may be recognized by a user via his tactile sensation or kinesthetic sensation. According to an embodiment, the haptic module 979 may include, for example, a motor, a piezoelectric element, or an electric stimulator.

The camera module 980 may capture a still image or moving images. According to an embodiment, the camera module 980 may include one or more lenses, image sensors, image signal processors, or flashes.

The power management module 988 may manage power supplied to the electronic device 901. According to one embodiment, the power management module 988 may be implemented as at least part of, for example, a power management integrated circuit (PMIC).

The battery 989 may supply power to at least one component of the electronic device 901. According to an embodiment, the battery 989 may include, for example, a primary cell which is not rechargeable, a secondary cell which is rechargeable, or a fuel cell.

The communication module 990 may support establishing a direct (e.g., wired) communication channel or a wireless communication channel between the electronic device 901 and the external electronic device (e.g., the electronic device 902, the electronic device 904, or the server 908) and performing communication via the established communication channel. The communication module 990 may include one or more communication processors that are operable independently from the processor 920 (e.g., the application processor (AP)) and supports a direct (e.g., wired) communication or a wireless communication. According to an embodiment, the communication module 990 may include a wireless communication module 992 (e.g., a cellular communication module, a short-range wireless communication module, or a global navigation satellite system (GNSS) communication module) or a wired communication module 994 (e.g., a local area network (LAN) communication module or a power line communication (PLC) module). A corresponding one of these communication modules may communicate with the external electronic device via the first network 998 (e.g., a short-range communication network, such as Bluetooth™, wireless-fidelity (Wi-Fi) direct, or infrared data association (IrDA)) or the second network 999 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 992 may identify and authenticate the electronic device 901 in a communication network, such as the first network 998 or the second network 999, using subscriber information (e.g., international mobile subscriber identity (IMSI)) stored in the subscriber identification module 996.

The wireless communication module 992 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 992 may support a high-frequency band (e.g., the millimeter wave (mmWave) band) to achieve, e.g., a high data transmission rate. The wireless communication module 992 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 992 may support various requirements specified in the electronic device 901, an external electronic device (e.g., the electronic device 904), or a network system (e.g., the second network 999). According to an embodiment, the wireless communication module 992 may support a peak data rate (e.g., 20 gigabits per second (Gbps) or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 997 may transmit or receive a signal or power to or from the outside (e.g., the external electronic device) of the electronic device 901. According to an embodiment, the antenna module 997 may include an antenna including a radiating element composed of a conductive material or a conductive pattern formed in or on a substrate (e.g., a printed circuit board (PCB)). According to an embodiment, the antenna module 997 may include a plurality of antennas (e.g., array antennas). In such a case, at least one antenna appropriate for a communication scheme used in the communication network, such as the first network 998 or the second network 999, may be selected, for example, by the communication module 990 (e.g., the wireless communication module 992) from the plurality of antennas. The signal or the power may then be transmitted or received between the communication module 990 and the external electronic device via the selected at least one antenna. According to an embodiment, another component (e.g., a radio frequency integrated circuit (RFIC)) other than the radiating element may be additionally formed as part of the antenna module 997.

According to various embodiments, the antenna module 997 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, commands or data may be transmitted or received between the electronic device 901 and the external electronic device 904 via the server 908 coupled with the second network 999. Each of the electronic devices 902 or 904 may be a device of a same type as, or a different type, from the electronic device 901. According to an embodiment, all or some of operations to be executed at the electronic device 901 may be executed at one or more of the external electronic devices 902 or 904, or the server 908. For example, if the electronic device 901 should perform a function or a service automatically, or in response to a request from a user or another device, the electronic device 901, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 901. The electronic device 901 may provide the outcome, with or without further processing of the outcome, as at least part of a reply to the request. To that end, a cloud computing, distributed computing, mobile edge computing (MEC), or client-server computing technology may be used, for example. The electronic device 901 may provide ultra low-latency services using, e.g., distributed computing or mobile edge computing. In another embodiment, the external electronic device 904 may include an internet-of-things (IoT) device. The server 908 may be an intelligent server using machine learning and/or a neural network. According to an embodiment, the external electronic device 904 or the server 908 may be included in the second network 999. The electronic device 901 may be applied to intelligent services (e.g., smart home, smart city, smart car, or healthcare) based on 5G communication technology or IoT-related technology.

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 940) including one or more instructions that are stored in a storage medium (e.g., internal memory 936 or external memory 938) that is readable by a machine (e.g., the electronic device 901). For example, a processor (e.g., the processor 920) of the machine (e.g., the electronic device 901) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A heat dissipation sheet comprising:
a plurality of graphene oxide particle layers including first graphene oxide particles having an average diameter of a first size and second graphene oxide particles having an average diameter of a second size; and
a fine crease structure including pores with a thickness of less than 2 μm between the plurality of graphene oxide particle layers.

2. The heat dissipation sheet of claim 1, wherein the first size is 18 μm to 22 μm, and the second size is 3 μm to 5 μm.

3. The heat dissipation sheet of claim 1, wherein a weight ratio of the first graphene oxide particles and the second graphene oxide particles is 50:50.

4. The heat dissipation sheet of claim 1, wherein the heat dissipation sheet has a thermal conductivity of at least 900 W/mK.

5. The heat dissipation sheet of claim 1, wherein the heat dissipation sheet includes the first graphene oxide particles, the second graphene oxide particles, and polyacrylonitrile (PAN) particles.

6. The heat dissipation sheet of claim 5, wherein the heat dissipation sheet further comprises a layered structure including the PAN particles between the plurality of graphene oxide particle layers.

7. The heat dissipation sheet of claim 5, wherein a weight ratio of the PAN particles to the first graphene oxide particles and second graphene oxide particles is 1:99.

8. The heat dissipation sheet of claim 5, wherein a molecular weight of the PAN particles has a value between 3,000 g/mol to 50,000 g/mol.

9. The heat dissipation sheet of claim 5, wherein the heat dissipation sheet has a thermal conductivity of at least 1200 W/mK.

10. The heat dissipation sheet of claim 9, wherein the heat dissipation sheet has a void of less than 0.5 μm.

11. A manufacturing method of a heat dissipation sheet, the manufacturing method comprising:
preparing a dispersion liquid by using a graphene oxide aqueous dispersion solution by compounding first graphene oxide particles having an average diameter of a first size and second graphene oxide particles having an average diameter of a second size in a specified weight ratio;
providing an initial film by applying or coating the dispersion liquid on a substrate;
performing annealing on the initial film; and
providing a heat dissipation sheet by compressing the initial film on which the annealing has been performed.

12. The manufacturing method for the heat dissipation sheet of claim 11, wherein the preparing of the dispersion liquid comprises:
preparing a polyacrylonitrile (PAN) aqueous dispersion solution by dispersing PAN particles in distilled water; and
mixing the PAN aqueous dispersion solution and the graphene oxide aqueous dispersion solution.

13. The manufacturing method for the heat dissipation sheet of claim 11, wherein the providing of the initial film comprises:
applying or coating the dispersion liquid on a substrate; and
separating the initial film provided by the dispersion liquid from the substrate.

14. The manufacturing method for the heat dissipation sheet of claim 11, wherein the performing of the annealing comprises:
maintaining the initial film in a high temperature state above a specified temperature; and
cooling the initial film.

15. The manufacturing method for the heat dissipation sheet of claim 14, wherein the specified temperature is 2300° C.

16. A mobile communication device comprising:
a housing including a first housing and a second housing rotatable with respect to the first housing;
a flexible display disposed over the first housing and the second housing;
a first reinforcing plate disposed to correspond to the first housing beneath the flexible display and a second reinforcing plate disposed to correspond to the second housing; and
a heat dissipation sheet attached to the first reinforcing plate, the second reinforcing plate, and the flexible display, and disposed between the first reinforcing plate, second reinforcing plate and the flexible display,
wherein the heat dissipation sheet includes,
a plurality of graphene oxide particle layers including first graphene oxide particles having an average diameter of a first size and second graphene oxide particles having an average diameter of a second size, and
a fine crease structure including pores with a thickness of less than 2 μm between the graphene oxide particle layers.

17. The mobile communication device of claim 16,
Wherein a heat source is disposed beneath the first reinforcing plate.

18. The mobile communication device of claim 17,
wherein the heat source includes at least one of an application processor (AP), a memory, a camera, an antenna, or a battery.

19. The mobile communication device of claim 17,
further comprising:
a printed circuit board (PCB),
wherein the heat source is disposed on the PCB.

20. The mobile communication device of claim 16,
wherein the heat dissipation sheet is formed by the first graphene oxide particles, the second graphene oxide particles, and polyacrylonitrile (PAN) particles.
